(19) United States
(12) Patent Application Publication
(10) Pub. No.: US 2026/0323817 A1
(43) Pub. Date: Oct. 15, 2026

(54) TRANSPARENT COPPER-CLAD LAMINATE AND MANUFACTURING METHOD THEREFOR

(71) Applicant: POMIRAN METALIZATION RESEARCH CO., LTD., TAOYUAN CITY (TW)

(72) Inventors: CHUNG-YI CHEN, TAOYUAN CITY (TW); NING CHANG, TAOYUAN CITY (TW); TSANG-SHENG KUO, TAOYUAN CITY (TW)

(73) Assignee: POMIRAN METALIZATION RESEARCH CO., LTD., TAOYUAN CITY (TW)

(21) Appl. No.: 19/642,684

(22) Filed: Apr. 9, 2026

(30) Foreign Application Priority Data
Apr. 11, 2025 (TW) 114113801

(51) Int. Cl. H05K 1/02

(52) U.S. Cl. CPC H05K 1/0274; H05K 2201/0338; H05K 2201/0344

(57) ABSTRACT

The present disclosure provides a transparent copper-clad laminate, including a transparent base material with first and second surfaces; a black seed layer formed on the first surface by dual electroless plating, with a sheet resistance of less than 10 Ω/sq and including nickel and zinc, where a weight ratio of zinc/nickel is 0.018-0.07; and a copper layer formed on a side of the black seed layer distal to the transparent base material and composited with the black seed layer to form a metal conductive layer; where the copper-clad laminate has a reflectance of less than 22% in the wavelength range of 400-700 nm for incident light at an incident angle of 5°, measured in a penetration direction from the second surface to the first surface of the transparent base material. A method for manufacturing the substrate is also provided to obtain a transparent copper-clad laminate having low reflectance.

### CROSS-REFERENCE TO RELATED APPLICATION

This non-provisional application claims priority under 35 U.S.C. § 119 (a) on Patent Application No(s). 114113801 filed in Taiwan, R.O.C. on Apr. 11, 2025, the entire contents of which are hereby incorporated by reference.

### BACKGROUND OF THE INVENTION

### 1. Field of the Invention

The present disclosure relates to a transparent copper-clad laminate (CCL) and a manufacturing method therefor, and in particular, to a transparent copper-clad laminate having low reflectance and a manufacturing method therefor.

### 2. Description of the Related Art

In the field of display manufacturing, copper traces are generally formed on a transparent base material to create transparent printed circuit boards (PCBs). However, because the copper traces have a metallic luster, there is a problem that the visibility of the display is reduced due to light reflection.

To address the above problem, it has been proposed to form a black layer between the copper traces and the transparent base material by a single electroless nickel-zinc alloy plating process to reduce the reflectance of the transparent printed circuit board.

### BRIEF SUMMARY OF THE INVENTION

Subsequently, the inventors of the present disclosure have found that the degree of blackening of the black layer exhibits a positive correlation with the zinc ion concentration in the plating bath; that is, the higher the zinc ion concentration, the more significant the blackness of the black layer. However, as the zinc ion concentration increases, the zinc ions hinder the deposition of the black layer, leading to a decrease in the plating rate and a looser plating structure, which in turn results in a sharp rise in the sheet resistance of the plating layer. Furthermore, if the sheet resistance of the black layer is too high (e.g., greater than 10 Ω/sq), it will adversely affect the production efficiency of Roll-to-Roll (RTR) continuous electroless plating and subsequent copper electroplating operations.

Therefore, there is room for further improvement regarding reducing the sheet resistance of the black layer in the transparent copper-clad laminate and improving the plating rate of the black layer.

The inventors of the present disclosure have found that by forming a black seed layer using a dual electroless plating method and a specific zinc/nickel ratio, the plating rate of the black seed layer can be improved while the sheet resistance of the black seed layer is reduced, and a transparent copper-clad laminate having low reflectance can be obtained.

To solve the above problems, a transparent copper-clad laminate according to one aspect of the present disclosure includes: a transparent base material including a first surface and a second surface; a black seed layer formed on the first surface by dual electroless plating, the black seed layer having a sheet resistance of less than 10 Ω/sq, and the black seed layer including nickel and zinc, where a weight ratio of zinc/nickel is 0.018-0.07; and a copper layer formed on a side of the black seed layer distal to the transparent base material and composited with the black seed layer to form a metal conductive layer; where the transparent copper-clad laminate has a reflectance of less than 22% in the wavelength range of 400-700 nm for incident light at an incident angle of 5°, measured in a direction of penetration from the second surface to the first surface of the transparent base material.

To solve the above problems, a method for manufacturing a transparent copper-clad laminate according to one aspect of the present disclosure includes: step (A): providing a transparent base material including a first surface and a second surface; step (B): forming a black seed layer on the first surface by performing dual electroless plating, the black seed layer having a sheet resistance of less than 10 Ω/sq, and the black seed layer including nickel and zinc, and a weight ratio of zinc/nickel being 0.018-0.07; and step (C): forming a copper layer on a side of the black seed layer distal to the transparent base material by electroplating, and the copper layer being composited with the black seed layer to form a metal conductive layer; where the transparent copper-clad laminate has a reflectance of less than 22% in the wavelength range of 400-700 nm for incident light at an incident angle of 5°, measured in a direction of penetration from the second surface to the first surface of the transparent base material.

In an embodiment, the transparent base material has a light transmittance of greater than 87% and is selected from the group consisting of: glass, polyimide (PI), polyethylene terephthalate (PET), cycloolefin polymer (COP), and polycarbonate (PC).

In an embodiment, the copper layer has a thickness of 0.2-20 μm.

In an embodiment, the black seed layer further contains phosphorus, and a content of phosphorus is 4 wt % or less of the black seed layer.

In an embodiment, a polymer coating is present between the transparent base material and the black seed layer, and the polymer coating has a light transmittance of greater than 85%.

In an embodiment, after the step (A) and before the step (B), a polymer coating is attached to a side of the transparent base material, and the polymer coating is located between the transparent base material and the black seed layer, and the polymer coating has a light transmittance of greater than 85%.

In an embodiment, a material of the polymer coating is selected from the group consisting of: polyimide (PI), polyurethane (PU), acrylic resin, and epoxy resin.

One aspect of the present disclosure is made in view of the above conventional problems, and an objective thereof is to provide a transparent copper-clad laminate. The aforementioned transparent copper-clad laminate can be formed with high production efficiency while having reduced reflectance.

Further, one aspect of the present disclosure is made in view of the above conventional problems, and an objective thereof is to provide a method for manufacturing a transparent copper-clad laminate. By means of the aforementioned manufacturing method, a transparent copper-clad laminate having low reflectance (e.g., less than 22% in the wavelength range of 400-700 nm) can be obtained.

### BRIEF DESCRIPTION OF THE DRAWINGS

FIG. 1 is a schematic cross-section view of a transparent copper-clad laminate according to an embodiment of the present disclosure.

FIG. 2 is a manufacturing flow diagram of a transparent copper-clad laminate according to an embodiment of the present disclosure.

FIG. 3 is a schematic measurement diagram of reflectance of a transparent copper-clad laminate according to the present disclosure.

FIG. 4 is a comparison chart of reflectance between Example 5 and Comparative Examples 4-5 of the present disclosure.

FIG. 5 shows an appearance photograph of an etched circuit of Example 5 in (a), and FIG. 5 shows an appearance photograph of an etched circuit of Comparative Example 1 in (b).

### DETAILED DESCRIPTION OF THE INVENTION

The following describes the implementation of the present disclosure through specific embodiments, and those skilled in the art can understand other advantages and effects of the present disclosure from the content disclosed in this specification. The present disclosure can also be implemented or applied through other different specific embodiments, and various details in this specification can also be modified and changed based on different viewpoints and applications without departing from the spirit of the present disclosure.

Unless otherwise stated in the text, the term “or” used in the specification and the appended claims includes the meaning of “and/or.”

Unless otherwise stated in the text, the term “A-B” used in the specification and the appended claims includes the meaning of “A or more and B or less.” For example, the term “10-40 weight % (wt %)” includes the meaning of “10 weight % or more and 40 weight % or less.”

### <Transparent Copper-Clad Laminate>

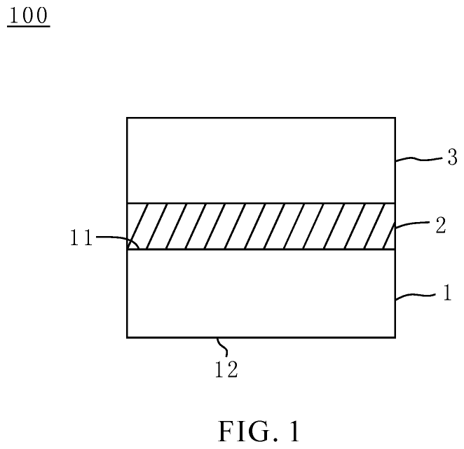

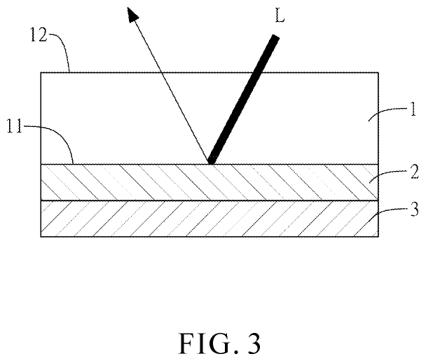

First, reference is made to FIG. 1, which is a schematic cross-section view of a transparent copper-clad laminate according to an embodiment of the present disclosure. As shown in FIG. 1, a transparent copper-clad laminate 100 according to one embodiment of the present disclosure includes: a transparent base material 1; a black seed layer 2; and a copper layer 3. The transparent base material 1 includes a first surface 11 and a second surface 12. The black seed layer 2 is formed on the first surface 11 by dual electroless plating, and the black seed layer 2 and the copper layer 3 may be composited to form a metal conductive layer. Furthermore, the transparent copper-clad laminate 100 has a reflectance of less than 22% in the wavelength range of 400-700 nm for incident light at an incident angle of 5°, measured in a direction of penetration from the second surface 12 to the first surface 11 of the transparent base material 1 (refer to FIG. 3 described later).

Subsequently, as shown in FIG. 1, the black seed layer 2 is formed on the first surface 11 of the transparent base material 1, and the copper layer 3 is formed on a side of the black seed layer 2 distal to the transparent base material 1. That is, the structure of the transparent copper-clad laminate 100 is the transparent base material 1, the black seed layer 2, and the copper layer 3 in sequence. Next, the transparent copper-clad laminate 100 of the present disclosure will be described in detail.

### <<Transparent Base Material>>

The material is not particularly limited as long as it has a light transmittance of greater than 87%, and any such material may be used as the transparent base material of the present disclosure. Furthermore, in consideration of weight reduction and the like, the transparent base material is preferably formed of a plastic material. Specifically, a material of the transparent base material may be selected from the group consisting of: glass, polyimide (PI), polyethylene terephthalate (PET), cycloolefin polymer (COP), and polycarbonate (PC). In a specific example, polyimide (PI) is selected for the transparent base material. The material source of the above transparent base material may be a commercially available product. For example, a transparent polyimide film manufactured by TAIMIDE TECH. INC., model name OT2-025, may be selected for the transparent base material.

### <<Black Seed Layer>>

The black seed layer has a sheet resistance of less than 10 Ω/sq, and includes nickel and zinc, and a weight ratio of zinc/nickel is 0.018-0.07. If the weight ratio of zinc/nickel is less than 0.018, the obtained transparent copper-clad laminate cannot achieve a desired reflectance (a reflectance of less than 22% in the wavelength range of 400-700 nm); on the other hand, if the weight ratio of zinc/nickel is greater than 0.07, the production conditions of the dual electroless plating will be limited, and the cost requirements will not be met. Furthermore, because an electroless plating bath includes sodium hypophosphite as a reducing agent, phosphorus is also co-deposited as one of alloy components in the reduction process of metal ions, where a content of phosphorus is preferably 4 wt % or less of the deposited alloy, and may be controlled via the solution composition and operating conditions of the electroless plating. By controlling the content of phosphorus to be 4 wt % or less of the black seed layer, the black seed layer can be etched completely, preventing it from remaining on the surface of the base material and causing short circuits.

In an embodiment, the black seed layer includes a ternary alloy of nickel, zinc, and phosphorus. In addition, a thickness of the black seed layer is preferably 50-250 nm, and more preferably 70-100 nm. If the thickness of the black seed layer is less than 50 nm, it will result in the sheet resistance of the black seed layer being too high (greater than 10 Ω/sq), which is not conducive to the subsequent electroplating of the copper layer. If the thickness of the black seed layer is greater than 250 nm, there is a risk of incomplete etching causing a short circuit.

In the present disclosure, the black seed layer is formed on a side of the transparent base material by dual electroless plating. Regarding dual electroless plating, it includes performing electroless plating twice in sequence, and the second electroless plating fills deposition defects of the plating layer formed by the first electroless plating, thereby improving the problem of excessively high sheet resistance generated by a single electroless plating of the black layer. Without increasing the total thickness of the plating layer, the sheet resistance of the black seed layer composited by dual electroless plating will decrease significantly, enabling subsequent RTR copper plating operations to proceed smoothly, and the plating rate during the dual electroless plating may be maintained at a certain level, which can ensure the efficiency of continuous production.

In addition, the reaction conditions of the first electroless plating and the second electroless plating are not particularly limited, and adjustments to the plating bath composition and reaction conditions may be made based on conventional electroless plating methods to obtain the black seed layer of the present disclosure. In the present disclosure, it is preferred that zinc ions necessary for the black seed layer are doped in the first plating bath of the first electroless plating, and no zinc ions are doped in the second plating bath of the second electroless plating to fill the deposition defects caused by the zinc ions in the plating layer formed by the first electroless plating.

### <<Copper Layer>>

The copper layer of the present disclosure is not particularly limited as long as it is a copper layer capable of forming subsequent etched circuits. Furthermore, in an embodiment of the present disclosure, it is preferred to plate the copper layer onto the black seed layer by means of electroplating. Regarding the electroplating solution used for the copper layer, it may be a commercially available product, for example, a copper sulfate electroplating solution (purchased from ALL-IN-LINE CHEMICALS ENTERPRISE CO., LTD.) or the like may be used. In addition, the thickness of the copper layer is preferably 0.2-20 μm.

Subsequently, in an embodiment, in order to increase the adhesion between the transparent base material and the black seed layer, a polymer coating (not shown) can be present between the transparent base material and the black seed layer. Moreover, in order to ensure the light-transmitting properties of the entire transparent copper-clad laminate, the light transmittance of the polymer coating needs to be greater than 85%. Specifically, a material of the polymer coating may be selected from the group consisting of: polyimide (PI), polyurethane (PU), acrylic resin, and epoxy resin. Similarly, the material source of the above polymer coating may be a commercially available product.

### <<Method for Manufacturing Transparent Copper-Clad Laminate>>

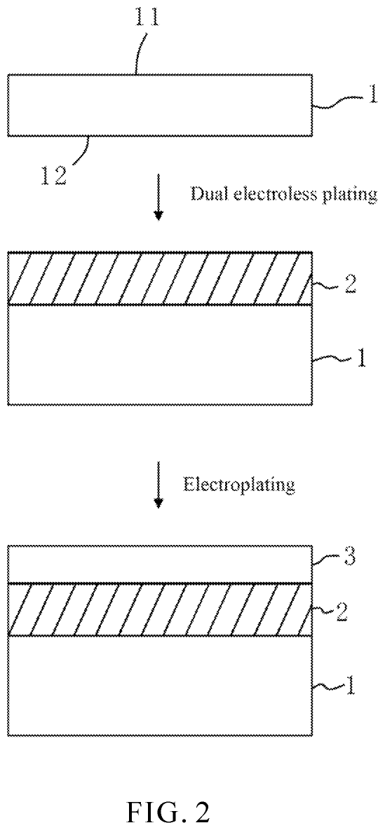

First, reference is made to FIG. 2, which is a manufacturing flow diagram of a transparent copper-clad laminate according to an embodiment of the present disclosure. As shown in FIG. 2, a method for manufacturing a transparent copper-clad laminate according to an embodiment of the present disclosure include: providing a transparent base material 1, which includes a first surface 11 and a second surface 12 (step A); forming a black seed layer 2 on the first surface 11 by performing dual electroless plating (i.e., performing a first electroless plating and a second electroless plating in sequence) (step B); and forming a copper layer 3 on a side of the black seed layer 2 distal to the transparent base material 1 by electroplating (step C).

Furthermore, in order to increase the adhesion between the transparent base material and the black seed layer, in an embodiment, after the step A and before the step B, a polymer coating (not shown) is coated on the first surface of the transparent base material, and the polymer coating is located between the transparent base material and the black seed layer.

Subsequently, regarding electroplating, a conventional electroplating method may be used. For example, the aforementioned transparent base material plated with the black seed layer is fixed with a stainless steel frame, first immersed in a 3 wt % H₂SO₄ solution for 1 minute to clean the surface, and then placed into a 20 L small copper electroplating tank (purchased from SURCHEM INTERNATIONAL CORP.) for electroplating. The electroplating area is 15 cm*15 cm, and the energization conditions may be a current of 6 A, a voltage of 3V, and a time of 2 minutes. Furthermore, regarding the electroplating solution, it may be an electroplating solution including 150 g/L of H₂SO₄, 120 g/L of CuSO₄, and chloride ions at a concentration of 50 ppm, and may further include an appropriate amount of a brightener and a leveling agent, which are not particularly limited. After electroplating, the transparent base material further plated with the copper layer is taken out, washed with water, and dried to obtain a single-sided copper-clad laminate with a copper thickness of approximately 1 μm.

Here, detailed contents regarding the dual electroless plating, the transparent base material, the black seed layer, the copper layer, and the polymer coating are as described above, and will not be repeated here.

### EXAMPLES

Hereinafter, the present disclosure will be specifically described by way of examples and comparative examples, but the present disclosure is not limited to these examples and comparative examples.

### [Measurement of Reflectance]

The reflectance of the transparent copper-clad laminate was measured using a spectrometer (model: JASCO/V-750) and a reflectance measurement kit (model: ISV-922) purchased from SUNWAY SCIENTIFIC CORPORATION. First, a 5 cm*5 cm sample was fixed at the position to be measured of the spectrometer, with the transparent base material side facing the integrating sphere, a white board for calibration was placed on the opposite side, the chamber cover was closed, and the analysis software was started to measure the reflectance at an incident angle of approximately 5°. Specifically, reference is made to FIG. 3, which is a schematic measurement diagram of reflectance of a transparent copper foil substrate according to the present disclosure. As shown in FIG. 3, by directing incident light in a direction of penetration from the second surface 12 to the first surface 11, the reflectance of incident light L with an incident angle of 5° in the wavelength range of 400 nm-700 nm can be measured.

### [Measurement of Peeling Strength]

The peeling strength between the transparent base material and the metal conductive layer in the transparent copper-clad laminate was measured using a universal tensile testing machine (model: QC-538M1) from COMETECH TESTING MACHINES CO., LTD. First, the thickness of the copper layer of the transparent copper-clad laminate was adjusted to 18 μm, and circuits were fabricated according to the test standard of IPC-TM-650 2.4.9, and a 90° peeling strength test was performed on the universal tensile testing machine.

### [Measurement of Sheet Resistance]

The sheet resistance of the transparent base material having the black seed layer was measured using a low-resistivity meter (model: LORESTA/MCP-T370) purchased from SOUTH & NORTH INTERNATIONAL CO., LTD. to evaluate whether a copper layer can be further electroplated on the black seed layer. First, a 10 cm*10 cm sample of the transparent base material having the black seed layer was placed on the measurement stage, and the sheet resistance of the black seed layer is measured by uniformly contacting with four-point probe, with the experimental data being the average value of 5 points.

### [Composition of Black Seed Layer]

Using an ICP optical emission spectrometer (model: PerkinElmer/Avio 200) purchased from CHENSHEN CO., LTD., a 6 cm*6 cm sample of the transparent base material having the black seed layer was taken and dissolved the black seed layer in 50 ml of aqueous nitric acid solution to form a solution to be tested. Before analysis, a calibration curve was prepared using standards, and then the solution to be tested was injected into the instrument to determine the volume concentration of each element, which was then converted into composition ratio accordingly.

### [Etched Circuit Inspection]

A sample of the transparent flexible circuit board was placed on the observation stage of a metallurgical microscope (model: Nikon LV100, purchased from LIN TRADING CO., LTD.), with the transparent PI side facing upward. The bottom of the circuit was inspected with a 20× objective lens to confirm the under-cut degree of the black plating layer of the circuit.

### [Overall Evaluation]

If at least one of the characteristics in Tables 1-2 below fails to meet the requirements, the overall evaluation is x; if at least one of the characteristics barely meets the requirements, the overall evaluation is Δ; if all the characteristics meet the requirements, the overall evaluation is ∘.

### Example 1

### (Pre-Treatment of Transparent Base Material)

First, a transparent polyimide film (model name OT2-025) manufactured by TAIMIDE TECH. INC. was used as the transparent base material, and continuous hydrophilic modification was performed on a corona treatment machine (manufactured by WEDGE CO., LTD., Japan). The operating conditions were a power of 3 kW and a speed of 3 m/min. Subsequently, the transparent base material was cut into a size of 15 cm*15 cm and immersed in a 2 wt % potassium hydroxide (KOH) solution at 40 °C for 150 seconds.

Next, referring to the SLP metallization process of OKUNO CHEMICAL INDUSTRIES CO., LTD., Japan, steps such as charge adjustment, pre-dipping, catalyzation, and acceleration were performed sequentially using SLP series electroless nickel plating reagents (including SLP-200, SLP-300, SLP-400, and SLP-500). The operating conditions are described as follows.

1. The pre-treated transparent base material was immersed in an SLP-200 solution at 65 °C for 75 seconds to perform charge adjustment, then taken out and washed with water. 2. It was continuously immersed in an SLP-300 solution at 25 °C for 25 seconds and in an SLP-400 solution for 75 seconds to attach the catalyst to the surface of the transparent base material, then taken out and washed with water. 3. Subsequently, it was immersed in an SLP-500 solution at 35 °C for 75 seconds to activate the catalyst, then taken out and washed with water to form a transparent base material with a palladium catalyst on both sides.

### (Dual Electroless Plating of Black Seed Layer)

Two 5-liter portions of SLP-660 electroless nickel plating solution from OKUNO CHEMICAL INDUSTRIES CO., LTD., Japan, were prepared. Both portions of the electroless nickel plating solution included 17-20 g/L of sodium hypophosphite and 4.6-5.0 g/L of nickel ions. One of the portions was taken and added with 0.004 mole/L of zinc sulfate and adjusted to pH=9.0 with ammonia water, which was used as the first plating bath; the other portion was not added with zinc sulfate and adjusted to pH=8.5 with ammonia water, which was used as the second plating bath.

The above transparent base material with a palladium catalyst on both sides was immersed in the first plating bath at a temperature of 55 °C for 80 seconds, then taken out and immediately immersed in the second plating bath at a temperature of 36 °C for 210 seconds, then taken out, washed with water, and dried to complete the dual electroless plating. Subsequently, the plating layer on a side was removed using a copper chloride etching solution to obtain a PI transparent base material having a black seed layer on a single side of Example 1.

### (Electroplating of Copper Layer)

The aforementioned transparent base material plated with the black seed layer was fixed with a stainless steel frame, first immersed in a 3 wt % H₂SO₄ solution for 1 minute to clean the surface, and then placed into a 20 L small copper electroplating tank (purchased from SURCHEM INTERNATIONAL CORP.) for electroplating. The electroplating area was 15 cm*15 cm, and the energization conditions were a current of 6 A, a voltage of 3V, and a time of 2 minutes. The electroplating solution included 150 g/L of H₂SO₄, 120 g/L of CuSO₄, and chloride ions at a concentration of 50 ppm. After electroplating, the transparent base material further plated with the copper layer was taken out, washed with water, and dried to obtain a single-sided copper foil substrate with a copper thickness of approximately 1 μm of Example 1.

### (Circuit Etching)

The transparent copper-clad laminate obtained in Example 1 was sequentially subjected to conventional modified semi-additive processes (mSAP) such as pre-treatment, dry film lamination, exposure, development, copper plating, stripping, and flash etching to separately prepare flexible circuit boards having a line width/line space of 20/100 μm or 30/120 μm. The flash etching operation involved fixing the semi-finished circuit that had completed pattern plating with a plastic frame, removing the dry film photoresist on the copper surface, and placing the product on a flash etching line to etch the underlying metal. Here, the flash etching solution included 5 wt % sulfuric acid, 10 wt % hydrogen peroxide, copper ions at a concentration of less than 30 g/L, and an appropriate amount of additives. The operating speed was 0.9 m/min. Upon completion, a flexible printed circuit board having fine circuits of Example 1 was obtained.

Finally, the dual electroless plating conditions, the composition of the black seed layer, and the characteristics of the black seed layer and the transparent copper-clad laminate for Example 1 are summarized in Table 1 described later.

### Examples 2-6

Subsequently, in the same manner as in Example 1, the conditions of the dual electroless plating and the composition of the black seed layer were changed based on Table 1 below to form transparent copper-clad laminates and flexible printed circuit boards of Examples 2-6. Furthermore, the dual electroless plating conditions, the composition of the black seed layer, and the characteristics of the black seed layer and the transparent copper-clad laminate for Examples 2-6 are summarized in Table 1 described later.

### Comparative Examples 1-3

In the same manner as in Example 1, the conditions of the dual electroless plating and the composition of the black seed layer were changed based on Table 1 above to form transparent copper-clad laminates and flexible printed circuit boards of Comparative Examples 1-3. Furthermore, the dual electroless plating conditions, the composition of the black seed layer, and the characteristics of the black seed layer and the transparent copper-clad laminate for Comparative Examples 1-3 are summarized in Table 1 described later.

### Comparative Example 4

First, in the same manner as in Example 1, pre-treatment of the transparent polyimide film was performed to form a transparent base material with a palladium catalyst on both sides.

Subsequently, 5 liters of SLP-660 electroless nickel plating solution from OKUNO CHEMICAL INDUSTRIES CO., LTD., Japan, was prepared in a beaker. The solution included 17-20 g/L of sodium hypophosphite and 4.6-5.0 g/L of nickel ions, and was adjusted to pH=8.5 with ammonia water. Then, the above PI transparent base material with a palladium catalyst on both sides was immersed in the electroless nickel plating solution at a temperature of 36 °C for 250 seconds, then taken out, washed and dried to complete electroless plating on both sides of the transparent base material. Next, the plating layer on a side was removed using a copper chloride etching solution to obtain a PI transparent base material having a nickel layer on a single side of Comparative Example 4. Thereafter, circuit etching was performed in the same manner as in Example 1 to obtain a flexible printed circuit board having fine circuits.

### Comparative Example 5

First, in the same manner as in Example 1, pre-treatment of the transparent polyimide film was performed to form a transparent base material with a palladium catalyst on both sides.

Subsequently, 5 liters of SLP-660 electroless nickel plating solution from OKUNO CHEMICAL INDUSTRIES CO., LTD., Japan, was prepared in a beaker. The solution included 17-20 g/L of sodium hypophosphite and 4.6-5.0 g/L of nickel ions, and 0.004 mole/L of zinc sulfate was added, and the pH was adjusted to 9.0 with ammonia water. Then, the above PI film with a palladium catalyst was immersed in the plating bath at a temperature of 55 °C for 400 seconds, then taken out, washed and dried to complete electroless plating on both sides of the transparent base material. Next, the plating layer on a side was removed using a copper chloride etching solution to obtain a PI transparent base material having a nickel-zinc alloy layer on a single side of Comparative Example 5. Thereafter, circuit etching was performed in the same manner as in Example 1, but it was found that in the case of a line width of 20 μm, a flexible printed circuit board having fine circuits could not be obtained due to metal trace peeling.

### Comparative Examples 6-7

Except for changing the conditions of the electroless plating to those shown in Table 2, PI transparent base materials having a nickel-zinc alloy layer on a single side of Comparative Examples 6-7 were obtained in the same manner as in Comparative Example 5. Thereafter, circuit etching was performed in the same manner as in Example 1, but it was found that in the case of line widths of 20 μm and 30 μm, operation was impossible due to metal trace peeling or excessively high resistance, and flexible printed circuit boards having fine circuits of Comparative Examples 6-7 could not be obtained. Furthermore, the electroless plating conditions, the composition of the plating layer, and the characteristics of the plating layer and the transparent copper-clad laminate for Comparative Examples 4-7 are summarized in Table 2 described later.

TABLE 1

| | First plating bath conditions | | | | | Second plating bath conditions | | | | |
|---|---|---|---|---|---|---|---|---|---|---|
| | First | Zn²⁺ | | | | Second | Zn²⁺ | | | |
| Experiment | plating | concentration | | Temperature | Time | plating | concentration | | Temperature | Time |
| number | solution | (mmole/L) | pH | (°C) | (sec) | solution | (mmole/L) | pH | (°C) | (sec) |
| Example 1 | SLP-660 | 4.0 | 9.0 | 55 | 80 | SLP-660 | 0 | 8.5 | 36 | 210 |
| Example 2 | | 5.5 | | | 90 | | | | | |
| Example 3 | | 7.0 | | | 110 | | | | | |
| Example 4 | | 7.0 | | | 140 | | | | | |
| Example 5 | | 7.0 | | | 170 | | | | | |
| Example 6 | | 8.5 | | | 170 | | | | | |
| Comparative | | 7.0 | | | 50 | | | | | |
| Example 1 | | | | | | | | | | |
| Comparative | | 7.0 | | | 80 | | | | | |
| Example 2 | | | | | | | | | | |
| Comparative | | 10.0 | | | 170 | | | | | |
| Example 3 | | | | | | | | | | |

| | Black seed layer characteristics | | | | | | |
|---|---|---|---|---|---|---|---|
| | | | | | Single-side | Plating | Sheet |
| Experiment | Elemental composition (wt %) | | | | thickness | rate | resistance |
| number | Nickel | Zinc | Phosphorus | Zinc/nickel | (nm) | (nm/sec) | (Ω/sq) |
| Example 1 | 94.1 | 2.5 | 3.4 | 0.027 | 85 | 0.293 | 6.3 |
| Example 2 | 93.8 | 2.7 | 3.5 | 0.029 | 86 | 0.286 | 6.2 |
| Example 3 | 94.4 | 1.8 | 3.8 | 0.019 | 87 | 0.272 | 5.9 |
| Example 4 | 93.9 | 2.6 | 3.5 | 0.028 | 92 | 0.263 | 5.8 |
| Example 5 | 92.5 | 3.9 | 3.6 | 0.042 | 97 | 0.255 | 5.1 |
| Example 6 | 93.7 | 2.8 | 3.5 | 0.030 | 91 | 0.239 | 5.3 |
| Comparative | 97.0 | 0.6 | 2.4 | 0.006 | 77 | 0.296 | 7.7 |
| Example 1 | | | | | | | |
| Comparative | 95.4 | 1.5 | 3.1 | 0.016 | 82 | 0.283 | 7.0 |
| Example 2 | | | | | | | |
| Comparative | 95.8 | 1.3 | 2.9 | 0.014 | 86 | 0.226 | 6.5 |
| Example 3 | | | | | | | |

Transparent copper foil substrate characteristics

| | |
|---|---|
| Peeling | Circuit etching |

| Experiment | Reflectance at | strength | Line width | Line width | Overall |
|---|---|---|---|---|---|
| number | 400-700 nm (%) | (kgf/cm) | 20 μm | 30 μm | evaluation |
| Example 1 | 20.2 | 0.54 | 20 | 30 | ∘ |
| Example 2 | 18.7 | 0.63 | 20 | 30 | ∘ |
| Example 3 | 20.5 | 0.53 | 19 | 29 | ∘ |
| Example 4 | 18.3 | 0.52 | 20 | 30 | ∘ |
| Example 5 | 17.6 | 0.52 | 22 | 31 | ∘ |
| Example 6 | 18.0 | 0.54 | 21 | 31 | Δ |
| Comparative | 29.8 | 0.61 | 16 | 20 | x |
| Example 1 | | | | | |
| Comparative | 24.0 | 0.55 | 18 | 28 | x |
| Example 2 | | | | | |
| Comparative | 29.1 | 0.56 | 17 | 26 | x |
| Example 3 | | | | | |

TABLE 2

Plating bath conditions

| | | Zn²⁺ | | | |
|---|---|---|---|---|---|
| Experiment | Electroless | concentration | | Temperature | Time |
| number | plating solution | (mmole/L) | pH | (°C) | (sec) |
| Comparative | SLP-660 | 0 | 8.5 | 36 | 250 |
| Example 4 | | | | | |
| Comparative | | 4.0 | 9.0 | 55 | 400 |
| Example 5 | | | | | |
| Comparative | | 7.0 | | | 500 |
| Example 6 | | | | | |
| Comparative | | 10.0 | | | 800 |
| Example 7 | | | | | |

| | Plating layer characteristics | | | | | | |
|---|---|---|---|---|---|---|---|
| | Elemental composition (wt %) | | | | Single-side | Plating | Sheet |
| Experiment | | | | Zinc/ | thickness | rate | resistance |
| number | Nickel | Zinc | Phosphorus | nickel | (nm) | (nm/sec) | (Ω/sq) |
| Comparative | 96.8 | 0.0 | 3.2 | 0.000 | 82 | 0.328 | 5.2 |
| Example 4 | | | | | | | |
| Comparative | 88.0 | 3.9 | 8.1 | 0.044 | 84 | 0.210 | 64 |
| Example 5 | | | | | | | |
| Comparative | 84.3 | 6.8 | 8.9 | 0.081 | 83 | 0.166 | 141 |
| Example 6 | | | | | | | |
| Comparative | 82.5 | 7.9 | 9.6 | 0.096 | 81 | 0.101 | 215 |
| Example 7 | | | | | | | |

| | FCCL characteristics | | | | |
|---|---|---|---|---|---|
| | Reflectance | Peeling | Circuit etching | | |
| Experiment | at 400-700 | strength | Line width | Line width | Overall |
| number | nm (%) | (kgf/cm) | 20 μm | 30 μm | evaluation |
| Comparative | 39.7 | 0.62 | 21 | 30 | x |
| Example 4 | | | | | |
| Comparative | 20.4 | 0.59 | Circuit peeling | 28 | x |
| Example 5 | | | | | |
| Comparative | 16.7 | 0.52 | Circuit peeling | Circuit peeling | x |
| Example 6 | | | | | |
| Comparative | 14.0 | 0.50 | Operation impossible | Operation impossible | x |
| Example 7 | | | | | |

First, as can be seen from Table 2, since Comparative Example 4 did not contain zinc (the zinc content is too low) and failed to meet the condition that the weight ratio of zinc/nickel is 0.018-0.07, the reflectance of the transparent copper-clad laminate of Comparative Example 4 in the wavelength range of 400-700 nm was 39.7%, which failed to meet the requirement, so the overall evaluation was x. In addition, regarding Comparative Example 5, although it met the condition that the weight ratio of zinc/nickel is 0.018-0.07, since a single electroless plating was performed in Comparative Example 5, the plating rate decreased (less than 0.24 nm/sec), resulting in a loose plating structure and excessively high sheet resistance (greater than 30 Ω/sq). In the case of a line width of 20 μm, a flexible printed circuit board having fine circuits could not be obtained due to metal trace peeling.

Then, as can be seen from Table 2, since Comparative Examples 6-7 had an excessively high zinc content and failed to meet the condition that the weight ratio of zinc/nickel is 0.018-0.07, and a single electroless plating was performed in Comparative Examples 6-7, the plating rate of the plating layer decreased (less than 0.24 nm/sec), resulting in a loose plating layer structure and excessively high sheet resistance (greater than 30 Ω/sq). In the case of line widths of 20 μm and 30 μm, operation was impossible due to metal trace peeling or excessively high sheet resistance, and flexible printed circuit boards having fine circuits could not be obtained.

Subsequently, as can be seen from Table 1, although Comparative Examples 1-3 used dual electroless plating, since the zinc content of Comparative Examples 1-3 was too low and failed to meet the condition that the weight ratio of zinc/nickel is 0.018-0.07, the reflectance of the transparent copper-clad laminate of Comparative Examples 1-3 in the wavelength range of 400-700 nm was 29.8%, 24.0%, and 29.1%, respectively, which failed to meet the requirement, so the overall evaluation was x. In addition, the line widths of Comparative Examples 1 and 3 were too narrow and lacked etching resistance.

Furthermore, as can be seen from Table 1, since Examples 1 to 6 all used dual electroless plating to form a black seed layer having a sheet resistance of less than 10 Ω/sq, and the weight ratio of zinc/nickel in the black seed layer was between 0.018 and 0.07, Examples 1 to 6 could obtain transparent copper-clad laminates having a reflectance of 22% or less in the wavelength range of 400-700 nm. In addition, Examples 1 to 6 could also subsequently produce flexible printed circuit boards having excellent circuit etching performance. Furthermore, since the plating rate of Example 6 was 0.239 nm/sec, which barely met the requirement of a plating rate of 0.24 nm/sec or more, the overall evaluation was Δ; and the overall evaluation of the remaining examples (Examples 1-5) was ∘.

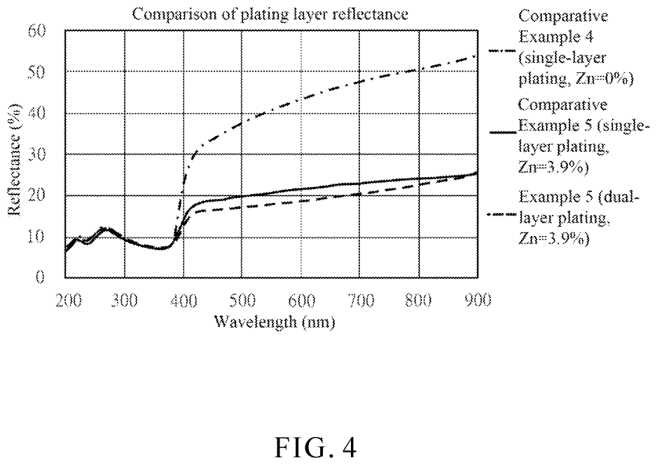

Subsequently, reference is made to FIG. 4, which is a comparison chart of reflectance between Example 5 and Comparative Examples 4-5 of the present disclosure. As shown in FIG. 4, since Comparative Example 4 did not contain zinc, the average reflectance in the wavelength range of 400-700 nm was 39.7%, which failed to meet the requirements. In addition, although the zinc content in the black seed layers of both Comparative Example 5 and Example 5 was 3.9 wt %, and the weight ratios of zinc/nickel in the black seed layers were also similar (both approximately 0.043), Example 5, through dual electroless plating, could further reduce the reflectance of the transparent copper-clad laminate, reduce the sheet resistance of the black seed layer, and increase the plating rate of the black seed layer, compared with Comparative Example 5 with single electroless plating. It can be seen from this that in the case of the same zinc content, the plating layer formed via dual electroless plating can achieve a better effect of reducing reflectance.

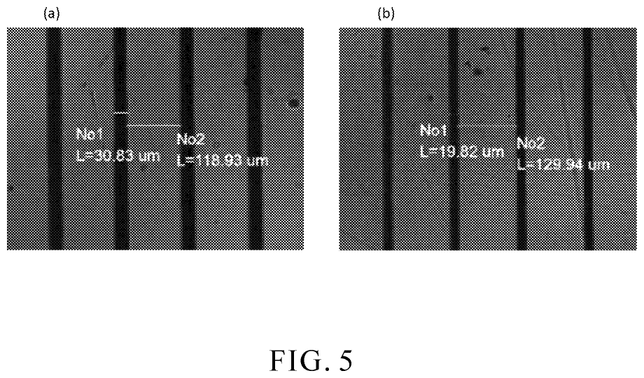

Finally, reference is made to FIG. 5, where FIG. 5(a) is an appearance photograph of an etched circuit of Example 5; and FIG. 5(b) is an appearance photograph of an etched circuit of Comparative Example 1. As shown in (a) of FIG. 5, in the case that the line width/line space of the etched circuit was 30/120 μm, the line width/line space of Example 1 was normal and met the specification. On the other hand, as shown in FIG. 5(b), in the case that the line width/line space of the etched circuit was 30/120 μm, the circuit of Comparative Example 1 was over-etched, resulting in a line width that was too narrow and a line spacing that was too large, thus failing to meet the specification.

The present disclosure is not limited to the above embodiments, various modifications can be made within the scope shown in the claims, and embodiments obtained by appropriately combining technical means disclosed in different embodiments are also included in the technical scope of the present disclosure.

While the present disclosure has been described by means of specific embodiments, numerous modifications and variations could be made thereto by those skilled in the art without departing from the scope and spirit of the present disclosure set forth in the claims.

What is claimed is:

1. A transparent copper-clad laminate, comprising:
a transparent base material comprising a first surface and a second surface;
a black seed layer formed on the first surface by dual electroless plating, the black seed layer having a sheet resistance of less than 10 Ω/sq, and the black seed layer comprising nickel and zinc, wherein a weight ratio of zinc/nickel is 0.018-0.07; and
a copper layer formed on a side of the black seed layer distal to the transparent base material and composited with the black seed layer to form a metal conductive layer;
wherein the transparent copper-clad laminate has a reflectance of less than 22% in the wavelength range of 400-700 nm for incident light at an incident angle of 5°, measured in a direction of penetration from the second surface to the first surface of the transparent base material.

2. The transparent copper-clad laminate according to claim 1, wherein the transparent base material has a light transmittance of greater than 87% and is selected from the group consisting of: glass, polyimide (PI), polyethylene terephthalate (PET), cycloolefin polymer (COP), and polycarbonate (PC).

3. The transparent copper-clad laminate according to claim 1, wherein a polymer coating is present between the transparent base material and the black seed layer, and the polymer coating has a light transmittance of greater than 85%.

4. The transparent copper-clad laminate according to claim 3, wherein a material of the polymer coating is selected from the group consisting of: polyimide (PI), polyurethane (PU), acrylic resin, and epoxy resin.

5. The transparent copper-clad laminate according to claim 1, wherein the black seed layer further comprises phosphorus, and a content of phosphorus is 4 wt % or less of the black seed layer.

6. A method for manufacturing a transparent copper-clad laminate, comprising:
step (A): providing a transparent base material comprising a first surface and a second surface;
step (B): forming a black seed layer on the first surface by performing dual electroless plating, the black seed layer having a sheet resistance of less than 10 Ω/sq, and the black seed layer comprising nickel and zinc, and a weight ratio of zinc/nickel being 0.018-0.07; and
step (C): forming a copper layer on a side of the black seed layer distal to the transparent base material by electroplating, and the copper layer being composited with the black seed layer to form a metal conductive layer;
wherein the transparent copper-clad laminate has a reflectance of less than 22% in the wavelength range of 400-700 nm for incident light at an incident angle of 5°, measured in a direction of penetration from the second surface to the first surface of the transparent base material.

7. The method for manufacturing a transparent copper-clad laminate according to claim 6, wherein the transparent base material has a light transmittance of greater than 87% and is selected from the group consisting of: glass, polyimide (PI), polyethylene terephthalate (PET), cycloolefin polymer (COP), and polycarbonate (PC).

8. The method for manufacturing a transparent copper-clad laminate according to claim 6, wherein the copper layer has a thickness of 0.2-20 μm.

9. The method for manufacturing a transparent copper-clad laminate according to claim 6, wherein after the step (A) and before the step (B), a polymer coating is coated on the first surface of the transparent base material, and the polymer coating is located between the transparent base material and the black seed layer.

10. The method for manufacturing a transparent copper-clad laminate according to claim 9, wherein the polymer coating has a light transmittance of greater than 85%, and a material of the polymer coating is selected from the group consisting of: polyimide (PI), polyurethane (PU), acrylic resin, and epoxy resin.

11. The method for manufacturing a transparent copper-clad laminate according to claim 6, wherein the black seed layer further comprises phosphorus, and a content of phosphorus is 4 wt % or less of the black seed layer.
